(19) United States
(12) Patent Application Publication
(10) Pub. No.: US 2010/0319773 A1
(43) Pub. Date: Dec. 23, 2010

(54) Optics for Concentrated Photovoltaic Cell

(75) Inventors: Robert Scott West, Pleasanton, CA (US); Nathanial James Czech, Airway Heights, WA (US)

Correspondence Address: PATENT LAW GROUP LLP, 2635 NORTH FIRST STREET, SUITE 223, SAN JOSE, CA, 95134, US

(73) Assignee: SOLARMATION, INC., Spokane, WA (US)

(21) Appl. No.: 12/489,384

(22) Filed: Jun. 22, 2009

(51) Int. Cl. H01L 31/00

(52) U.S. Cl. 136/259

(57) ABSTRACT

A concentrated photovoltaic (CPV) module includes a CPV cell mounted on a support surface. A primary optical element (POE) is a square Fresnel lens fixed in position over the CPV cell. A secondary optical element (SOE) is optically coupled to the cell for providing uniform light over the surface of the cell. The SOE has a square, sloping top portion and a truncated pyramid shaped bottom portion that tapers toward the cell. The top portion is formed of angled flat square rings that refract light entering the top portion from the POE. The bottom portion mixes the light using TIR. The SOE has an angled middle portion, and an integral support structure having one end attached to the middle portion surrounds the bottom portion and is attached to the cell support surface so there is little mechanical stress on the cell.

### FIELD OF THE INVENTION

This invention relates to an optical system for concentrating sunlight onto a small solar cell and, in particular, to an optical system that employs refraction, rather than mirrors, to concentrate sunlight onto the solar cell.

### BACKGROUND

A concentrated photovoltaic (CPV) system comprises an array of small solar cells (e.g., 1 cm² or less), where each cell receives light directed to it by an optical system that tracks the sun. The optical system for each cell typically has a light receiving area that is hundreds of times the area of the cell, so that the cell effectively receives energy from hundreds of suns. The alignment of the optical system to the sun (typically within one degree) is very important to maximize the energy impinging on the cell surface and maximize the uniformity of the light distribution over the cell surface.

Such a system differs from less expensive solar cell systems where large panels of single-junction silicon cells are mounted in a fixed position on a rooftop. Such a system is generally referred to as a photovoltaic (PV) system, rather than a CPV system. A PV system has an overall efficiency of about 18%.

A CPV cell typically has a stack of three semiconductor junctions, having the electrical characteristics of three diodes in series. Each junction is formed of a different set of semiconductor materials so as to be sensitive to a different range of wavelengths. The three groups of wavelengths are typically UV, visible, and infrared. Therefore, CPV systems use more of the sun's energy, and fewer CPV cells are needed to achieve the same power output as a PV system. Such CPV systems typically have an overall efficiency of about 28%.

A common optical system for a CPV system comprises a large area Fresnel lens, called a primary optical element (POE), that ideally focuses all of the impinging sunlight onto a receiving surface of a much smaller secondary optical element (SOE). The SOE is directly optically coupled to the cell, such as by a transparent adhesive. The SOE mixes the light from the POE and has the goal of providing uniform illumination of the cell.

The prior art optical systems, especially the SOE portions, suffer from drawbacks such as not achieving uniform light distribution, being very sun-alignment sensitive, being difficult to fabricate due to the robust materials needed to not degrade when subjected to the UV energy of hundreds of suns, and providing stress on the cell since the SOE is typically directly attached to the cell's top surface.

What is needed is a CPV optical system where the SOE provides more uniform distribution of brightness and wavelengths over the cell surface, has a wider light acceptance angle from a rectangular Fresnel lens (the POE), is easy to fabricate, and does not exert significant mechanical stress on the cell.

### SUMMARY

An optically system for a standard CPV cell, having a top surface area of about 1 cm² or less, is described. A large rectangular (includes square) Fresnel lens is spaced from an SOE, such as by 10 cm. The Fresnel lens, in one embodiment, is a square having an area of about 625 cm² (e.g., 25 cm per side).

The SOE has a bottom portion that resembles a truncated inverted pyramid shape. The bottom surface of the SOE has an area that matches the area of the cell and is optically coupled to the top surface of the cell with silicone. The top portion of the SOE comprises a light receiving surface that is made up of a small center square surrounded by rectangular concentric rings, where the inner rings are slightly angled up and the outer rings are at increasingly downward angles as the rings extend to the outer edge of the SOE, so that the top surface generally falls away toward the edges. In one embodiment of an SOE designed for a cell of about 3×3 mm, the size of the inlet top surface is about 9×9 mm and the SOE has a total height of about 14 mm.

Since the Fresnel lens is rectangular, the light impinging on the SOE is generally rectangular and impinges on the top surface of the SOE at various angles. Since the SOE has a rectangular light receiving surface and concentric angled rectangular rings, the SOE top surface efficiently receives the light from the Fresnel lens at the various angles and improves light acceptance uniformity over its surface. The light entering through the rings is refracted downward by the SOE, and the light is totally internally reflected (TIR) by the bottom portion of the SOE so as to mix the incoming light to provide a uniform brightness and wavelength distribution over the cell surface.

Between the sloping top portion and the truncated pyramid shaped bottom portion is a middle portion that has an inward angle connecting the outer square perimeter of the top portion to the narrower bottom portion. The angle of the middle portion is such that light refracted from the outer areas of the top portion does not significantly exit through the angled sides of the middle portion. The middle portion allows the edges of the top portion to overhang the outer edges of the bottom portion to accept more light at wider angles from the POE. This also allows the taper of the bottom portion to be at a steep angle to provide TIR of the light refracted by the top portion.

The designs of the POE and SOE are such that light is not focused at a point or in a plane within the SOE. Rather, the Fresnel rings are designed to distribute their focal areas in a relatively large three-dimensional volume within the SOE to reduce the UV concentration and help enable better mixing of the light. In one embodiment, the Fresnel rings have a cloverleaf shape to distribute the focal areas inside of the SOE, where each Fresnel ring arc has a different focal point. In one embodiment, the focal areas extend along a 6 mm path within the SOE (about half the height of the SOE). Since the UV from many suns is not focused within a small point or area, the SOE material may be silicone instead of glass. Silicone is easy to mold, so the SOE can be made inexpensively with a stringent tolerance.

Since the SOE is silicone, it can be optically coupled to the top surface of the cell using a silicone adhesive. To avoid the cell fully supporting the SOE, the SOE is molded to have an integral support structure connected to the middle portion of the SOE. The support structure may consist of four flat walls that are spaced from the bottom portion of the SOE by an air gap so as not to affect the TIR of the bottom portion. The middle portion is angled such that an insubstantial amount of light is tapped off by the support structure. The bottom surface of the support structure is adhesively affixed to the circuit board (or other substrate) supporting the cell.

In another embodiment of the SOE 18, the top down shape is not square but may be any shape, depending on the shape of the cell and POE. Additionally, the concentric rings on the SOE 18 need not be flat but may be rounded and form a smooth sloping surface.

Other features are also described.

### BRIEF DESCRIPTION OF THE DRAWINGS

FIG. 1A is a simplified and condensed cross-sectional view of the optical system providing light to a CPV cell, where the POE may be spaced from the SOE by over ten times the height of the SOE.

FIG. 1B is a close up of the top of the SOE.

FIG. 1C is a side view of the SOE supported over a cell, where FIG. 1A is a cross-section along the line 1A-1A in FIG. 1C.

FIG. 1D is a top down view of the SOE, illustrating the rectangular concentric facets of the top surface and the surrounding integral support structure of the SOE, where FIG. 1A is a cross-section along the line 1A-1A in FIG. 1D

FIG. 2A illustrates results from a computer simulation of light rays from the POE, when the POE is aligned with the sun, showing that a focal volume extends from about the top of the SOE to about half way into the SOE.

FIG. 2B is a close up of results from a computer simulation of light rays from the POE, when the POE is one degree off-axis with the sun, illustrating how most of the rays enter the SOE through the SOE's outer rings.

FIG. 3A is a simplified cross-sectional view of the SOE showing an approximate volume within which the various Fresnel prism arcs focus light.

FIG. 3B is a simplified top down view of the SOE showing an approximate volume within which the various Fresnel prism arcs focus light.

FIG. 4 illustrates the general shape of the focal pattern formed by selected rings in the Fresnel lens at different depths into the SOE.

FIG. 5 is a perspective view of one of many possible examples of a cell module containing the SOE of FIG. 1A.

FIG. 6 is a top down view of the Fresnel lens used as the POE, where there are 33 clover shaped rings in one embodiment, each ring quadrant being formed by an arc of a circle with its center point within the quadrant rather than at the center point of the lens.

Elements labeled with the same numeral are the same or equivalent.

### DETAILED DESCRIPTION

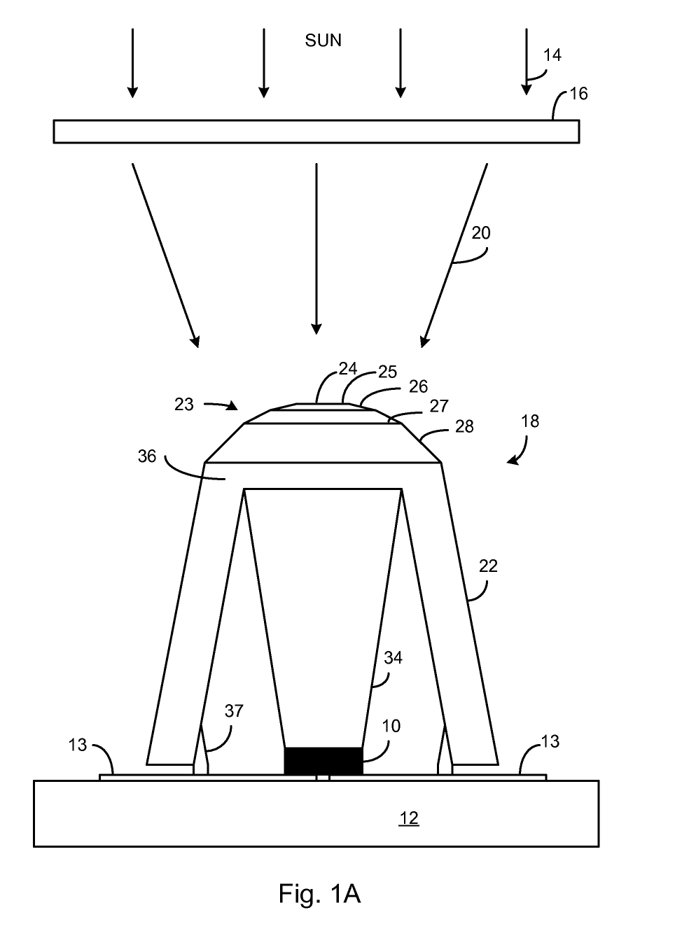

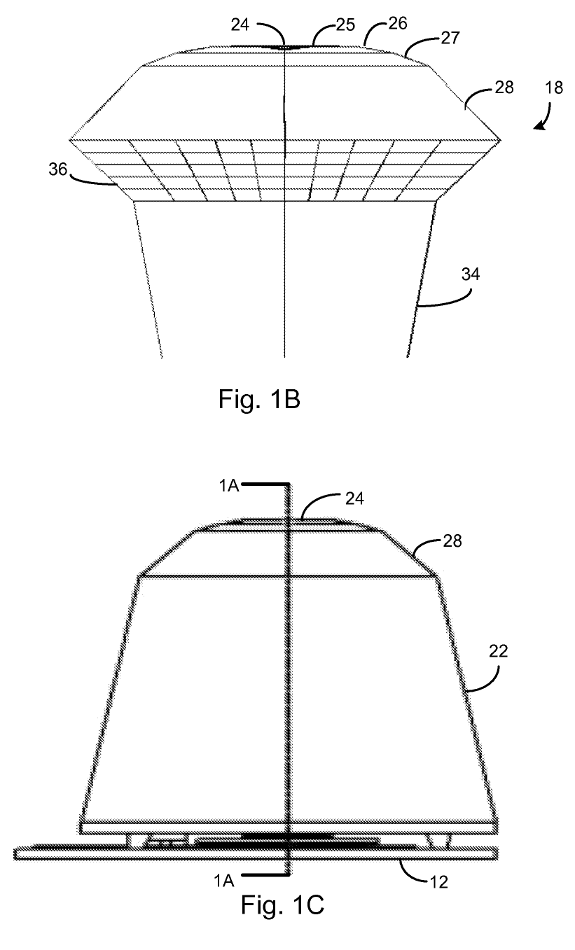

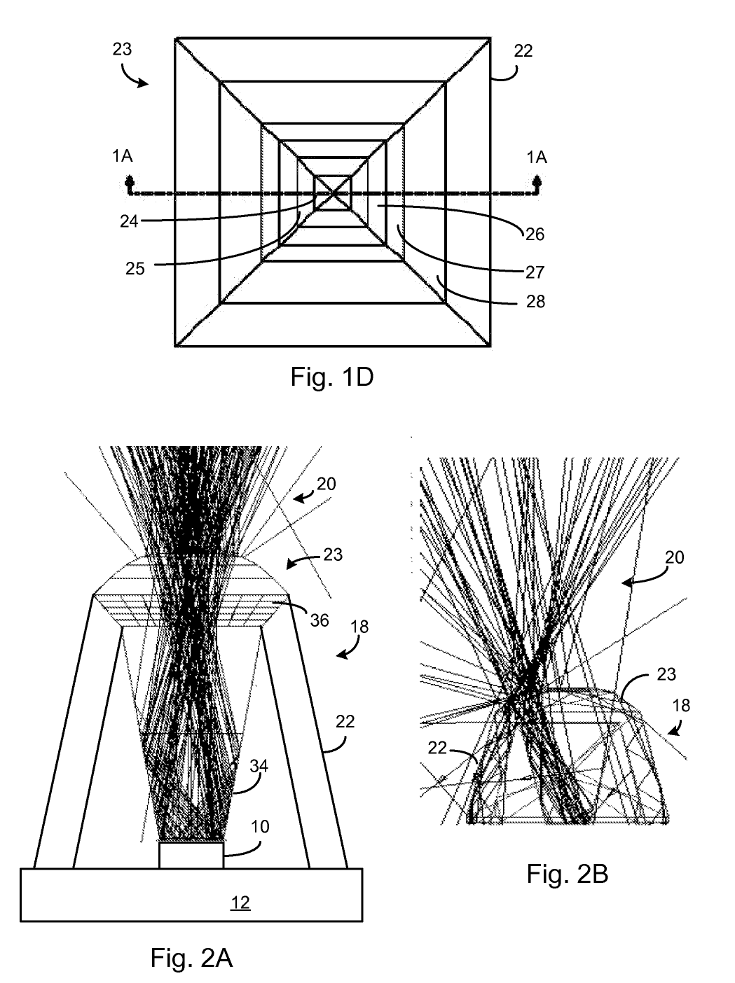

FIG. 1A is a cross-sectional view of a CPV module comprising an optical system and a CPV cell 10 mounted on a circuit board 12 or other substrate. The board 12 may be any electrically insulating substrate (e.g., ceramic) with electrical connectors for the cell 10. The cell 10 may be mounted on the board 12 via a submount, which is then connected to the board 12. The board 12 typically contains electrical connections for interconnecting identical cells in parallel to create a large current. In one embodiment, the cell 10 is a commercially available cell that generates about 6.8 amps at 2.68 volts using the optical system described herein. The cell 10 is preferably a triple junction cell, where each junction comprises different materials for the wavelength ranges of UV, visible, and infrared. The board 12 generally has a top metal layer 13 for connection to electrodes on each cell 10, a connector for interconnection with other cells, and a heat sink layer for removing the high heat applied to each cell 10. The cell 10 and board 12 may be conventional, and the board 12 is intended to represent any support surface for the cell 10.

The combination of the cell 10, board 12, and optical system is a module that is connected together by a housing, frame, or other structure to maintain the proper spacing and alignment.

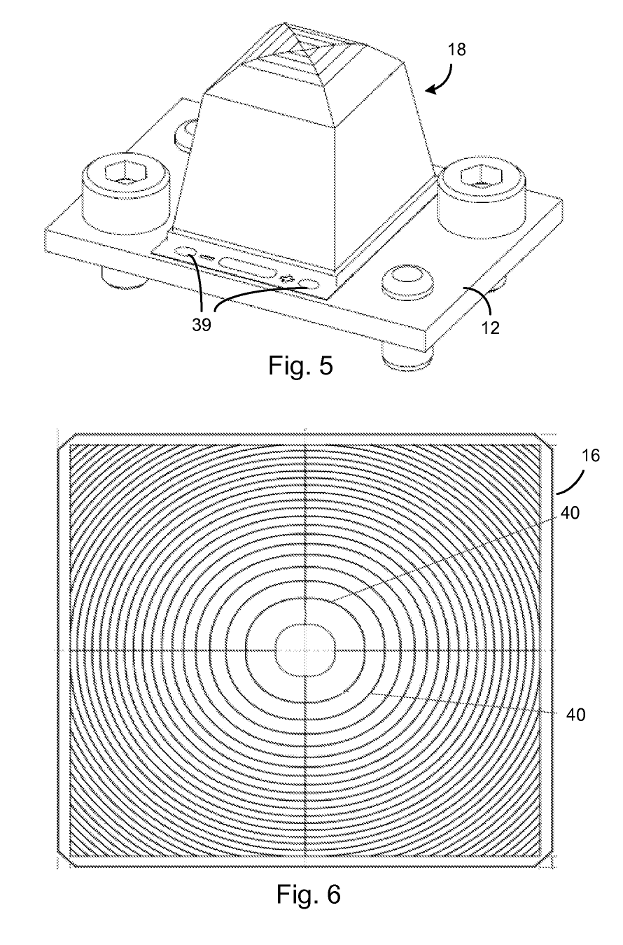

FIG. 1A illustrates the module aligned with the sun so that the rays 14 are substantially normal to the primary optical element (POE) 16 (sun rays actually have a divergence of about 0.26 degrees). The POE 16 is a Fresnel lens having rings of differently angled prisms, described later in more detail with respect to FIG. 4. The POE 16 has an area that may be over 1000 times that of the cell 10. In one embodiment, the cell 10 is a square having sides between 2.8 mm and 10 mm. For a 3.3×3.3 mm cell, the POE 16 is 94×94 mm for 1000 times the area and, for a 10×10 mm cell, the POE is 316×316 mm for 1000 times the area.

The angled prisms of the POE 16 direct the sunlight toward the top surface of a secondary optical element (SOE) 18, as shown by rays 20. In one embodiment, the POE 16 is spaced about 10 cm from the top of the SOE 18, and the height of the SOE 18 is about 14 mm.

FIG. 1B is a close-up view of the top portion of the SOE 18.

FIG. 1C is a side view of the SOE 18 supported over a cell, where FIG. 1A is a cross-section along the line 1A-1A in FIG. 1C.

FIG. 1D is a top down view of the SOE 18, where the width of the square top portion 23 (not including the support structure 22 in FIG. 1A) is about 8.8 mm. The SOE 18 tapers to the size of the cell 10, such as 2.8×2.8 mm.

The top portion 23 of the SOE 18 comprises a flat center area 24 and four square concentric rings 25-28. The inner ring 25 slightly angles upward and rings 26-28 progressively increase in angle downward toward the edge so that each of the rings is generally normal to the light rays impinging on it from the POE 16. There may be more inner or outer rings in an actual embodiment. For example, as shown in FIG. 1A, light rays from the POE 16 near the edge of the POE 16 impinge upon the SOE 18 at a greater angle and are primarily received by the outer rings 26-28, especially if the optical system is not aligned with the sun. Conversely, the light from near the center of the POE 16 impinges upon the center area 24 and inner ring 25. Therefore, the POE 16 ring angles and SOE 18 shape are designed so that the light refracted by certain rings of the POE 16 impinge upon certain rings of the SOE 18 to provide a large focal area and uniformity of light. In one embodiment, the angle of the most outer ring 28 of the SOE 18 is about 45 degrees relative to the flat center area 24.

The generally downward slope of the SOE 18 top surface, in conjunction with its relatively wide width, provides a wide acceptance angle of light so the module does not need to be perfectly aligned with the sun. As the module becomes more out of alignment with the sun, more light will impinge upon the outer rings of the SOE 18. Since each quadrant of the SOE 18 is identical, and each quadrant of the POE 16 is identical, there is very uniform light mixing inside the SOE 18.

FIG. 2A illustrates a computer simulation of rays 20 from the POE 16 when the POE 16 is aligned with the sun. The rays 20 are “softly” focused within the SOE 18 so that there is a large three-dimensional volume within the SOE 18 where the light is focused from the different prism rings in the POE 16. In one embodiment, the focal points begin near the top of the SOE 18 and extend about 6 mm into the SOE 18, which is about half the height of the SOE 18. The prism rings in the POE 16 are made non-circular so that the focal points do not just extend along a line down the center of the SOE 18. By making the prism rings non-circular, the UV entering the SOE 18 is diffused, enabling the SOE 18 to be formed of silicone rather than a more UV tolerant glass or other transparent material. Silicone is inexpensive and easily moldable.

The light rays 20 are mixed in the bottom portion 34 of the SOE 18, where the light rays 20 reflect off the flat side walls by TIR. The bottom portion 34 has a truncated pyramid shape that extends from the cell surface to the middle portion 36 of the SOE 18.

FIG. 2B is a close-up of a computer simulation of rays 20 from the POE 16 when the POE 16 is one degree off-axis with the sun. As seen, more of the rays 20 enter the SOE 18 from the outer rings of the top portion 23, and more of the light is tapped off by the support structure 22. Thus, the system is less efficient when not aligned with the sun; however, the shape of the top portion 23 causes it to accept more light from the POE without reflection, compared to prior art SOE's.

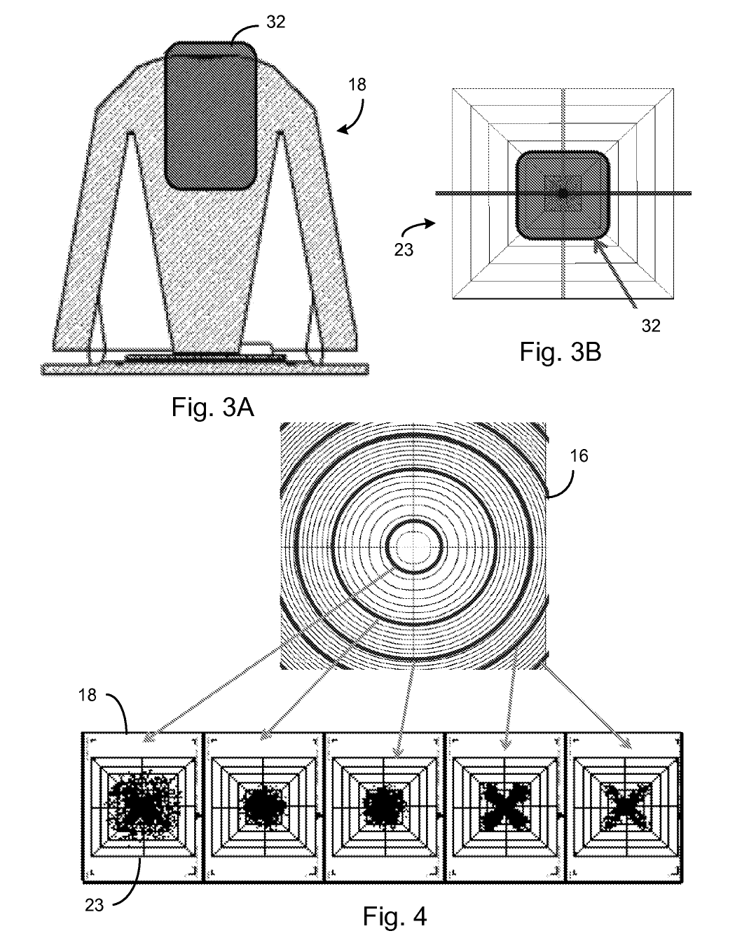

FIG. 3A illustrates the general focal volume 32 inside of the SOE 18 and slightly above the SOE 18 when the POE 16 is aligned with the sun and focuses the light rays 20 from the various rings of the POE 16. FIG. 3B is a top down view of the focal volume 32.

The focal volume 32 has different cross-sectional shapes along its length since the different rings of the POE 16 create different patterns. For example, as shown in FIG. 4, the unbroken rings of the POE 16 create a generally circular focal pattern, and the broken outer rings of the POE 16 create an X shape focal pattern. The different top down views of the SOE 18 show the focal patterns at the depth at which the rays are best focused by the associated POE ring. The distribution of the focal patterns within the SOE 18 avoids any high UV concentrations, enabling the SOE 18 to be formed of silicone. In one embodiment, the depth of the focal volume 32 is about 6 mm, or about one-half the height of the SOE 18.

The SOE 18 can be formed of a thermoset silicone. Thermoset silicone can be easily molded using injection molding or compression molding. In one embodiment, the SOE 18 is molded directly over the board 12 (or other support surface) on which many cells 10 are mounted, so that many SOE's are formed simultaneously. The molding and curing process causes the SOE 18 to be adhered to the cell 10 and board 12 (including adhered to metal pads or conductors, etc.) without any special adhesive step.

The SOE 18 can be easily molded to include the integral support structure 22, shown in FIG. 1A. The support structure 22 is generally a square skirt spaced from and surrounding the SOE 18 except where it is attached at the angled middle portion 36. The angle of the middle portion 36 causes the outer surface of the middle portion 36 to not intersect any light rays refracted by the top portion 23 (when the system is aligned to the sun) so an insubstantial amount of light is tapped off by the silicone support structure 22. The angled middle portion 36 allows the outer refracting ring 28 to extend over the edge of the bottom portion 34 to increase the acceptance angle of light from the POE 16, while allowing the angled walls of the bottom portion 34 to have a relatively small angle to ensure TIR.

FIG. 1A shows the support structure 22 affixed to the metal layer 13 surface of the board 12 by a small integral silicone tab 37. The tab 37 just allows the SOE 18 to be supported with a smaller footprint. The tab 37 can be located anywhere on the bottom of the support structure 22 to provide the least interference on the board 12. The tab 37 is optional. In one embodiment, where the support structure 22 is affixed to the board 12 by a silicone adhesive, the tab 37 may represent the silicone adhesive. The support structure 22 may be affixed to the insulating surface of the board 12 if the metal layer 13 does not extend around the cell 10.

In one embodiment, the flat bottom surface of the bottom portion 34 is affixed to the top of the cell 10 by a silicone adhesive for good optical coupling. Since the SOE 18 is primarily supported by the support structure 22 affixed to the circuit board 12 (or other support structure) the SOE 18 does not mechanically stress the cell 10.

In another embodiment, the support structure 22 is not angled outward but is still separated from the bottom portion 34 by an air gap so as not to affect the TIR of the bottom portion 34. In another embodiment, the support structure 22 is an extension of the top portion 23 rather than connected to the middle portion 36. The support structure need not completely surround the bottom portion 34. Many configurations of the support structure 22 are possible.

FIG. 5 is a perspective view of the SOE 18 supported on a board 12, where electrodes 39 on the board 12 lead to the cell. The board 12 (having a metal body for heat conduction) is intended to be bolted to a heat sink (not shown).

In another embodiment of the SOE 18, the top down shape is not square but may be any shape, depending on the optimal shape required for the system, such as depending on the shape of the cell and POE. The shape may also be a non-square rectangular, round, polygonal, or other shape. Additionally, the concentric rings on the SOE 18 need not be flat but may be rounded and form a smooth sloping surface (no separate rings).

FIG. 6 is a top down view of the POE 16, showing the non-symmetrical prism rings 40 to spread out the focal area in the SOE 18. Each ring 40 may have a height of about 1 mm. FIG. 6 illustrates a clover leaf pattern of the rings 40 formed by quadrants of circle portions, where the center point of each circle is within the quadrant rather than at the center point of the POE 16, creating a non-symmetrical ring pattern. Other patterns may be used, such as rings having eight or more lobes. In one embodiment, there are 33 rings 40 on the POE 16.

The combination of the POE 16 and SOE 18 provides substantially uniform light over the top surface of the cell, where both brightness and wavelengths are uniformly distributed so that the three diode junctions in the cell are fully exposed to the concentrated sunlight for maximum current output.

Having described the invention in detail, those skilled in the art will appreciate that given the present disclosure, modifications may be made to the invention without departing from the spirit and inventive concepts described herein. Therefore, it is not intended that the scope of the invention be limited to the specific embodiments illustrated and described.

What is claimed is:

1. A concentrated photovoltaic (CPV) module comprising:
a CPV cell supported by a support surface;
a primary optical element (POE) fixed in position over the CPV cell, the POE being a substantially rectangular Fresnel lens having refracting non-symmetrical prisms to create a three-dimensional diffused focal volume; and
a secondary optical element (SOE) fixed in position relative to the POE, the SOE having a top portion and a substantially rectangular bottom portion, the top portion sloping downward towards an outer edge of the SOE, the top portion refracting light entering the top portion from the POE, the bottom portion comprising sides that taper towards the cell, wherein the sides perform total internal reflection of light entering the top portion, a bottom surface of the bottom portion being optically coupled to and affixed to a top surface of the cell.

2. The module of claim 1 wherein the top portion of the SOE is substantially square.

3. The module of claim 1 wherein the top portion is substantially rectangular.

4. The module of claim 3 wherein the top portion comprises substantially rectangular flat concentric rings, wherein the rings comprise rings that are at increasingly downward angles as the rings progress towards an outer edge of the SOE, the rings refracting light entering the top portion from the POE.

5. The module of claim 3 wherein the sides of the bottom portion are flat.

6. The module of claim 1 wherein the SOE has a middle portion between the top portion and the bottom portion, an outermost portion of the SOE extending over an outer edge of the bottom portion, the middle portion extending between an outer edge of the top portion and an outer edge of the bottom portion at an angle shallower than an angle of the sides of the bottom portion.

7. The module of claim 6 wherein the SOE further comprises an integral support structure having one end attached to the middle portion and at least partially surrounding the bottom portion, a bottom of the support structure being affixed to the support surface on which the cell is supported.

8. The module of claim 7 wherein the support surface on which the cell is supported comprises an insulating substrate surface on which is formed a metal layer underlying and connected to the cell, wherein the integral support structure is directly affixed to the insulating substrate surface.

9. The module of claim 1 wherein the support surface on which the cell is supported is an insulating substrate surface on which is formed a metal layer underlying and connected to the cell, wherein the integral support structure is directly affixed to the metal layer.

10. The module of claim 1 wherein the SOE is molded silicone.

11. The module of claim 10 wherein the SOE is molded directly over the cell and support surface.

12. The module of claim 1 wherein a majority of the three-dimensional diffused focal volume produced by the POE occurs internal to the SOE.

13. The module of claim 12 wherein the three-dimensional diffused focal volume extends down into the SOE at least within a middle third of a height of the SOE.

14. The module of claim 1 wherein the refracting non-symmetrical prisms of the POE are formed in a cloverleaf pattern.

15. The module of claim 1 wherein the top portion of the SOE has sides less than 15 mm, and the cell has sides less than 6 mm.

16. The module of claim 1 wherein the top portion comprises a flat square center area, the top portion further comprising substantially rectangular flat concentric rings, wherein the rings comprise one or more inner rings surrounding the flat square that are at upward angles, and the one or more inner rings are surrounded by outer rings that are at increasingly downward angles as the rings progress towards an outer edge of the SOE.

17. A concentrated photovoltaic (CPV) module comprising:
a CPV cell supported by a support surface;
a primary optical element (POE) fixed in position over the CPV cell; and
a molded secondary optical element (SOE) formed of a transparent first material, the SOE being fixed in position relative to the POE, the SOE having a top portion performing refraction of light entering the top portion from the POE, the SOE having a bottom portion having sides that taper towards the cell performing total internal reflection of light entering the top portion, a bottom surface of the bottom portion being optically coupled to a top surface of the cell,
the SOE having an integral support structure formed of the first material, the support structure being separated from the bottom portion by a gap, a bottom surface of the support structure being affixed to the support surface on which the cell is supported.

18. The module of claim 17 wherein the SOE has a middle portion between the top portion and the bottom portion, the top portion extending over an outer edge of the bottom portion, the middle portion extending between an outer edge of the top portion and an outer edge of the bottom portion at an angle shallower than an angle of the bottom portion, wherein the integrated support structure has one end attached to the middle portion.

19. The module of claim 17 wherein the integral support structure substantially surrounds the bottom portion.

20. The module of claim 17 wherein the SOE is a molded silicone.

21. The module of claim 17 wherein the top portion is substantially rectangular, the bottom portion has flat tapering sides, and the integral support structure has flat walls that at least partially surround the bottom portion.

22. The module of claim 17 wherein the support surface on which the cell is mounted is an insulating substrate surface on which is formed a metal layer underlying and connected to the cell, wherein the integral support structure is directly affixed to the insulating substrate surface.

23. The module of claim 17 wherein the support surface on which the cell is mounted is an insulating substrate surface on which is formed a metal layer underlying and connected to the cell, wherein the integral support structure is directly affixed to the metal layer.

24. The module of claim 17 wherein a center area of the top portion is a flat square, and the rings comprising one or more inner rings surrounding the flat square that are at upward angles, and the one or more inner rings are surrounded by the rings that are at increasingly downward angles as the rings progress towards an outer edge of the SOE.
